(19) United States
(12) Patent Application Publication
(10) Pub. No.: US 2010/0245751 A1
(43) Pub. Date: Sep. 30, 2010

(54) DISPLAY DEVICE AND MANUFACTURING METHOD THEREOF

(75) Inventors: Takahiko MUNEYOSHI, Higashiyamato (JP); Yasushi Nakano, Tokyo (JP); Susumu Sasaki, Chiba (JP); Tomio Yaguchi, Sagamihara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/727,268

(22) Filed: Mar. 19, 2010

(30) Foreign Application Priority Data
Mar. 25, 2009 (JP) 2009-074058

(51) Int. Cl. G02F 1/1345; H01L 27/02; H01L 21/77; H01J 9/20

(52) U.S. Cl. 349/149; 257/59; 438/30; 445/46; 257/E27.009; 257/E21.535

(57) ABSTRACT

When a display device is formed using a plastic substrate, a yield is increased for separating individual display devices from a mother substrate. On a mother TFT substrate, plural TFT substrates are formed each of which includes a display region and terminal portions. On a mother opposed substrate formed of a plastic substrate having a thickness of 200 μm or less, display regions are formed so as to correspond to the display regions formed on the mother TFT substrate. On the mother opposed substrate, terminal openings are formed beforehand so as to correspond to the terminal portions formed on the mother TFT substrate. With this configuration, when the display devices are separated from the mother substrate, it is not necessary to perform half cutting for exposing the terminal portions, so that the display devices can be manufactured with high yields.

### CLAIM OF PRIORITY

The present application claims priority from Japanese Patent Application JP 2009-074058 filed on Mar. 25, 2009, the content of which is hereby incorporated by reference into this application.

### BACKGROUND OF THE INVENTION

1. Field of the Invention

The present invention relates to a display device and particularly relates to a display device which can be flexibly bent by using a plastic substrate.

2. Description of the Related Art

Liquid crystal displays can be reduced in thickness, size, and weight and thus have been widely used in various fields. Further, organic electroluminescent displays under development can also be reduced in thickness, size, and weight. These displays have glass substrates. Since glass is brittle, thin displays have a problem of mechanical reliability. Moreover, displays using glass substrates are hard to flexibly bend. Organic electroluminescent displays under development have the same problem.

In order to achieve thin, unbreakable, and bendable displays, it has been examined to change the material of a substrate from glass to plastic. A liquid crystal display is formed of, for example, a TFT substrate on which pixels including thin-film transistors (TFTs) and pixel electrodes are formed in a matrix and scanning lines and video signal lines are formed, and an opposed substrate on which color filters are formed.

For example, in order to improve the manufacturing efficiency of liquid crystal displays, a number of liquid crystal display panels (combinations of TFT substrates and opposed substrates) are formed on a mother substrate and then individual liquid crystal cells are separated from the mother substrate. The mother substrate is made up of a mother TFT substrate on which plural TFT substrates are formed and a mother opposed substrate on which plural opposed substrates are formed. In other words, the mother substrate is formed by bonding the mother TFT substrate and the mother opposed substrate.

When individual liquid crystal display panels are separated from the mother substrate, it is necessary to cut the mother substrate into the individual liquid crystal display panels (full cutting) and perform half cutting of partially removing the opposed substrates to expose terminals on the TFT substrates.

Japanese Patent Laid-Open No. 2004-118135 describes a configuration in which liquid crystal displays are not inspected one by one but plural liquid crystal display panels formed on a mother substrate are inspected while located on the mother substrate. In Japanese Patent Laid-Open No. 2004-118135, terminal portions on the mother substrate are exposed by removing portions of a mother opposed substrate so as to correspond to the terminal portions, allowing inspections on the liquid crystal displays. In Japanese Patent Laid-Open No. 2004-118135, scribes are formed by a wheel chip, which is shaped like a bead on an abacus, to expose the terminal portions, and then the mother opposed substrate is partially removed by an impact applied to the mother substrate, so that the terminal portions are exposed. In Japanese Patent Laid-Open No. 2004-118135, a mother TFT substrate and the mother opposed substrate are both glass substrates.

Full-cutting methods for separating individual liquid crystal display panels from a mother substrate include a scribing method, a laser method, and a dicing method. In the scribing method, a surface of a glass substrate is scratched with a super hard material such as a diamond chip and the substrate is split by a pressure applied from the back side. In the laser cutting method, a plastic substrate or the like is irradiated with a carbon dioxide gas laser and so on and is cut by thermal sublimation.

Half cutting according to the scribing method is performed particularly using the brittleness of glass. In half cutting according to the dicing method, just a small part of a substrate is left by controlling the depth of a blade and then the part is mechanically broken. In half cutting with a laser, just a small part of the thickness of a substrate is left by controlling a heat quantity and then the left part is mechanically broken.

### SUMMARY OF THE INVENTION

The problems of a liquid crystal display will be described below as examples. Other kinds of thin displays such as organic electroluminescent displays have the same problems.

In the case where individual liquid crystal display panels are separated from a mother substrate formed by bonding a mother TFT substrate on which plural TFT substrates are formed and a mother opposed substrate on which plural opposed substrates are formed, it is necessary to separate the individual liquid crystal display panels by full cutting. Further, in order to expose terminal portions on the TFT substrates, it is necessary to remove portions of the opposed substrates by half cutting so as to correspond to the terminal portions.

However, when plastic is used for the mother substrate, the substrate has low brittleness unlike glass. Thus it is difficult to perform half cutting on the substrate according to the scribing method. Further, in the case of half cutting by laser cutting, it is necessary to strictly control a heat quantity and thus it is difficult to increase productivity.

Moreover, when a thin plastic substrate is used, a ratio of unevenness to the thickness of the substrate increases and the substrate becomes wavy. Thus it is difficult to control the focal position of a laser beam on the plastic substrate, so that a thickness to be left is hard to control during half cutting. Further, a substrate having a small thickness is easily deformed by an external force and thus panels may be broken when portions left in cutting are mechanically removed. Half cutting by dicing has the same problem as laser cutting.

The present invention has been made to efficiently perform, with a high yield, half cutting for forming terminal portions in a liquid crystal display formed by separating a liquid crystal panel from a mother substrate using plastic.

The present invention has been made to solve the foregoing problems. Specific means will be described below.

(1) A mother opposed substrate that is opposed to a mother TFT substrate having plural TFT substrates and has plural opposed substrates disposed in opposition to the TFT substrates, the TFT substrate having terminal portions and a display region in which pixels made up of TFTs and pixel electrodes are formed in a matrix, wherein the mother opposed substrate has terminal openings formed on portions corresponding to the terminal portions formed on the mother TFT substrate, and the mother opposed substrate is made of plastic with a thickness of 200 μm or less.

(2) The mother opposed substrate according to (1), wherein the mother opposed substrate has a side longer than the other sides of the mother opposed substrate and can be rolled up.

(3) A manufacturing method of a display device formed of a pair of a first substrate having a display region and terminal portions formed thereon and a second substrate, the method including the steps of: forming the plural first substrates on a mother first substrate; forming the second substrates on a mother second substrate so as to correspond to the display regions of the first substrates and forming terminal openings on the mother second substrate so as to correspond to the terminal portions of the first substrates, the mother second substrate being made of plastic with a thickness of 200 μm or less; forming a mother substrate by bonding the mother first substrate and the mother second substrate; and separating the pair of the first substrate and the second substrate from the mother substrate.

(4) The manufacturing method of a display device according to (3), wherein a splitting line that splits the pair of the first substrate and the second substrate from the mother substrate has at least one side located inside the terminal opening.

(5) A manufacturing method of a liquid crystal display formed of a pair of a TFT substrate and an opposed substrate having color filters and spacers, the TFT substrate having terminal portions and a display region in which pixels including TFTs and pixel electrodes are formed in a matrix, the method including the steps of: forming the plural TFT substrates on a mother TFT substrate; forming the plural opposed substrates on a mother opposed substrate so as to correspond to the display regions of the TFT substrates, the mother opposed substrate being made of plastic with a thickness of 200 μm or less; forming terminal openings on portions of the mother opposed substrate so as to correspond to the terminal portions of the TFT substrates, after forming the color filters and the spacers; forming a mother substrate by bonding the mother TFT substrate and the mother opposed substrate; and separating the pair the TFT substrate and the opposed substrate from the mother substrate.

(6) A display device including a first substrate having a display region and terminal portions and a second substrate opposed to the first substrate, wherein the second substrate is made up of a first region including a display region and a second region not including a display region, the second substrate has terminal openings formed in regions corresponding to the terminal portions of the first substrate, the second region of the second substrate is not opposed to the display region of the first substrate and the terminal portions of the first substrate, the first substrate and the first region of the second substrate are bonded with a sealing material, and the first substrate and the second region of the second substrate are bonded with the sealing material.

(7) A manufacturing method of a passive display device, the passive display device including: a first substrate having plural first electrodes formed to extend in a first direction, and a second substrate having plural second electrodes formed to extend in a second direction, the first and second electrodes having pixels formed on the points of intersection of the first and second electrodes so as to constitute a display region, the plural first electrodes having a first terminal portion formed on the ends of the first electrodes, the plural second electrodes having a second terminal portion formed on the ends of the second electrodes, the method including the steps of: forming the plural first substrates on a mother first substrate made of plastic with a thickness of 200 μm or less; forming the plural second substrates on a mother second substrate made of plastic with a thickness of 200 μm or less; forming terminal openings on portions of the mother first substrate so as to correspond to second terminals formed on the second substrates; forming terminal openings on the mother second substrate so as to correspond to first terminals formed on the first substrates; forming a mother substrate by bonding the mother first substrate and the mother second substrate; and separating the individual passive display devices from the mother substrate.

According to the present invention, the mother opposed substrate is formed of a plastic substrate having a thickness of 200 μm or less and the terminal openings are formed beforehand on portions corresponding to the terminal portions formed on the mother TFT substrate, thereby eliminating the need for half cutting on the terminal portions when the mother substrate formed by bonding the mother TFT substrate and the mother opposed substrate is divided to form the individual display devices. Thus when the mother opposed substrate is formed of a plastic substrate, it is possible to increase a manufacturing yield for dividing the mother substrate into the individual display devices.

### BRIEF DESCRIPTION OF THE DRAWINGS

FIG. 1 is an exploded plan view showing a first embodiment of the present invention;

FIG. 2 is an exploded plan view showing another form of the first embodiment of the present invention;

FIG. 3 is an exploded plan view showing still another form of the first embodiment of the present invention;

FIG. 4 shows an example of a mother opposed substrate according to the first embodiment of the present invention;

FIG. 5 shows an example of the substrate used for the first embodiment of the present invention;

FIG. 6 shows another example of the substrate used for the first embodiment of the present invention;

FIG. 7 shows still another example of the substrate used for the first embodiment of the present invention;

FIG. 8 is a plan view showing a part of a combination of a mother TFT substrate and a mother opposed substrate;

FIG. 9 is a plan view showing a state in which a liquid crystal display panel is cut;

FIG. 10 is a sectional view of the liquid crystal display panel;

FIG. 11 is a sectional view showing a liquid crystal display panel having another configuration;

FIG. 12 is a sectional view of an organic electroluminescent display panel;

FIG. 13 is a sectional view showing an electrophoretic panel;

FIG. 14 is an exploded perspective view of a passive liquid crystal display panel;

FIG. 15 shows a manufacturing process of the liquid crystal display panel according to the first embodiment of the present invention;

FIG. 16 is an exploded plan view showing a mother TFT substrate and a mother opposed substrate of related art;

FIG. 17 is a perspective view showing a liquid crystal display panel;

FIGS. 18A to 18E show a separating method of the liquid crystal display panel according to a scribing method; and

FIGS. 19A to 19E show a separating method of the liquid crystal display panel with a laser.

### DETAILED DESCRIPTION OF THE INVENTION

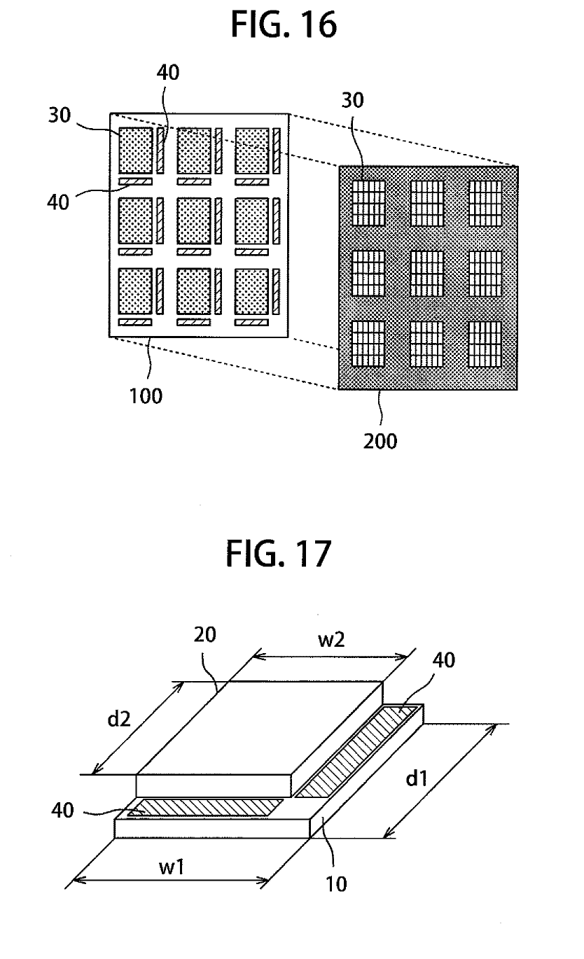

Before description of specific embodiments of the present invention, related art of the present invention will be described below. FIG. 16 shows a manufacturing method of a typical liquid crystal display. In FIG. 16, on a mother TFT substrate 100, plural TFT substrates 10 are formed (shown in FIG. 17) each of which is made up of a display region 30 and terminal portions 40. On a mother opposed substrate 200, plural opposed substrates 20 are formed (shown in FIG. 17). By bonding the mother TFT substrate 100 and the mother opposed substrate 200, display regions 30 formed on the mother opposed substrate 200 are matched with the display regions 30 formed on the TFT substrate 100.

In FIG. 16, the mother opposed substrate 200 and the mother TFT substrate 100 are bonded with a sealing material. The sealing material is formed between the TFT substrates 10 formed on the mother TFT substrate 100 and the opposed substrates 20 formed on the mother opposed substrate 200 and is also formed around the mother opposed substrate 200 and the mother TFT substrate 100.

Generally, the sealing material is formed on the sides of the opposed substrates 20. After the sealing material is formed, for example, a liquid crystal is added dropwise into the sealing material and then the opposed substrates 20 and the TFT substrates 10 are bonded to each other, so that the liquid crystal is sealed in each liquid crystal display panel. When the liquid crystal is not added dropwise but is added by vacuum suction through a sealing inlet, individual liquid crystal display panels are separated from the mother substrate and then the liquid crystal is added to each of the liquid crystal display panels.

FIG. 17 is a perspective view showing a state in which the liquid crystal display panel is cut from the mother substrate of FIG. 16. In FIG. 17, the TFT substrate 10 has a width of w1 and a length of d1 and the opposed substrate 20 has a width of w2 and a length of d2. The terminal portions 40 are formed on the extended portions of the TFT substrate 10 from the opposed substrate 20.

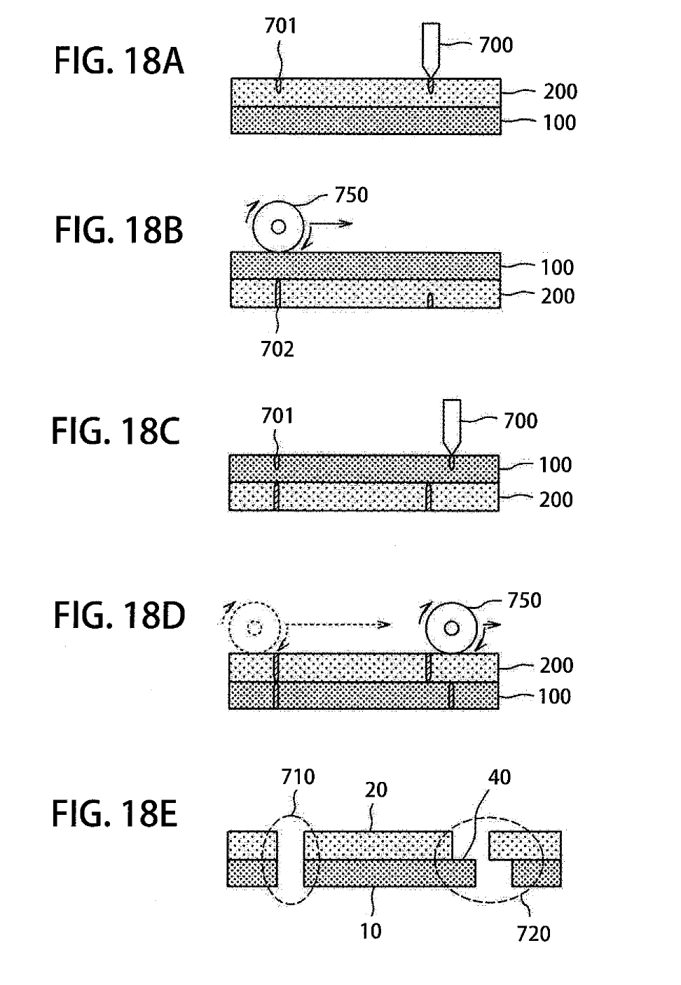

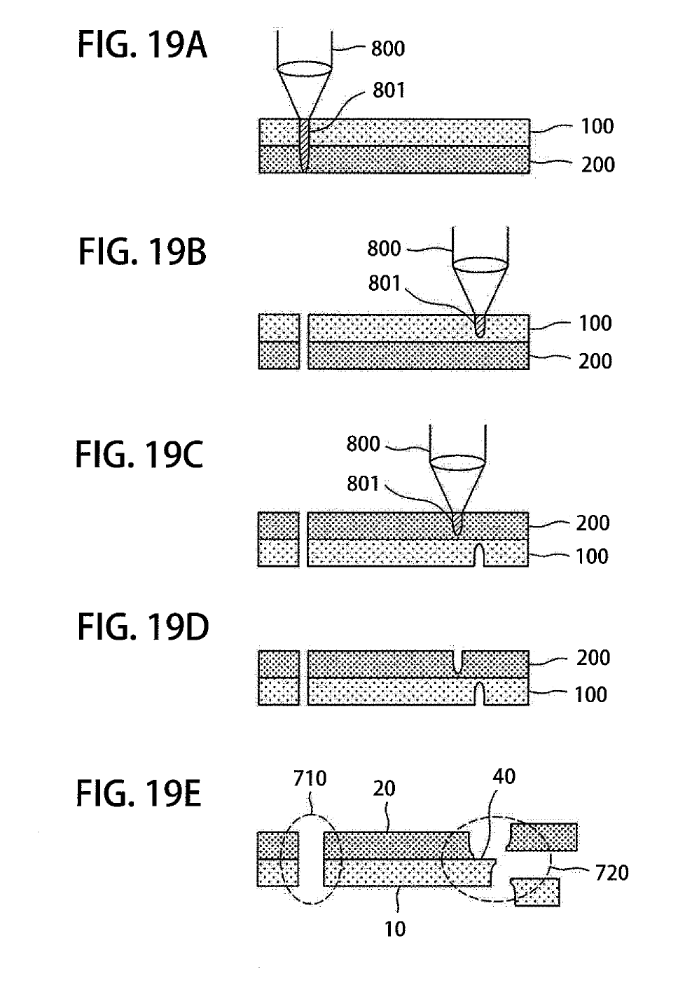

FIGS. 18A to 18E and 19A to 19E show methods of separating the liquid crystal display panel of FIG. 17 from the mother substrate of FIG. 16. FIGS. 18A to 18E show a scribing method and FIGS. 19A to 19E shows splitting by a laser.

First, the scribing method will be described with reference to FIGS. 18A to 18E. In FIG. 18A, scribes 701 are formed on each liquid crystal display panel by an ultra hard material chip 700 in a state in which the mother opposed substrate 200 and the mother TFT substrate 100 are bonded to each other. Next, as shown in FIG. 18B, a pressure is applied from the side of the mother TFT substrate 100 with a roller 750, so that the mother opposed substrate 200 is split at the scribes 701 as indicated by 702.

Next, as shown in FIG. 18C, scribes 701 are formed at necessary points on the side of the mother TFT substrate 100 with the ultra hard material chip 700. After that, as shown in FIG. 18D, a pressure is applied from the side of the mother opposed substrate 200 with the roller 750, so that the mother TFT substrate 100 is split at the scribes 701.

Thus, as indicated by 710 (full cutting) in FIG. 18E, the liquid crystal display panel made up of the TFT substrate 10 and the opposed substrate 20 is separated from the mother substrate. Since the scribes 701 are formed at different positions on the mother TFT substrate 100 and the mother opposed substrate 200, the terminal portions 40 can be exposed on the TFT substrate 10. Consequently, half cutting 720 shown in FIG. 18E is possible. However, the process of FIGS. 18A to 18E can be performed because the mother TFT substrate 100 and the mother opposed substrate 200 are made of glass having brittleness.

FIGS. 19A to 19E show the case where the mother TFT substrate 100 and the mother opposed substrate 200 are formed of plastic substrates. When the mother opposed substrate 200 or the mother TFT substrate 100 is made of plastic, it is difficult to use the scribing method illustrated in FIG. 18A to 18E. In FIGS. 19A to 19E, a liquid crystal display panel is separated from the mother substrate by a laser 800.

In FIG. 19A, the laser 800 is emitted to a splitting line for separating the liquid crystal display panel, the plastic is sublimated according to a heat quantity of the laser 800, and a melted portion 801 is formed. In FIG. 19A, the mother TFT substrate 100 and the mother opposed substrate 200 are simultaneously melted and cut.

Next, as shown in FIG. 19B, the laser 800 is emitted to the side of the mother TFT substrate 100 to form a melted portion 801. At this point, the intensity of the laser 800 is adjusted such that the depth of the melted portion 801 leaves a small thickness of the mother TFT substrate 100. Next, as shown in FIG. 19C, the laser 800 is emitted to a predetermined position of the mother opposed substrate 200 to form a melted portion 801. At this point, the intensity of the laser 800 is adjusted such that the depth of the melted portion 801 leaves a small thickness of the mother opposed substrate 200. FIG. 19D is a schematic sectional view of the mother substrates formed thus.

After that, the small left portions of the mother TFT substrate 100 and the mother opposed substrate 200 are removed so as to be mechanically ripped off, so that the liquid crystal display panel made up of the TFT substrate 10 and the opposed substrate 20 can be obtained as shown in FIG. 19E. At this point, full cutting and half cutting can be switched by controlling the heat quantity of the emitted laser 800. Half cutting is performed on the mother opposed substrate 200 to expose the terminal portion 40 of the TFT substrate 10.

However, in the method using the laser 800, it is difficult to accurately adjust the intensity of the laser 800 particularly in a half cutting process. The laser 800 having an extremely high intensity breaks wires and terminals formed on the TFT substrate 10, and the laser 800 having an extremely low intensity cannot sufficiently cut the mother opposed substrate 200, so that it is difficult to separate individual liquid crystal display panels from the mother substrate.

The present invention described in the following embodiments has been made to overcome these problems and can correctly separate individual liquid crystal display panels with a high yield from a mother substrate formed of a mother opposed substrate 200 and a mother TFT substrate 100 which are made of plastic.

### First Embodiment

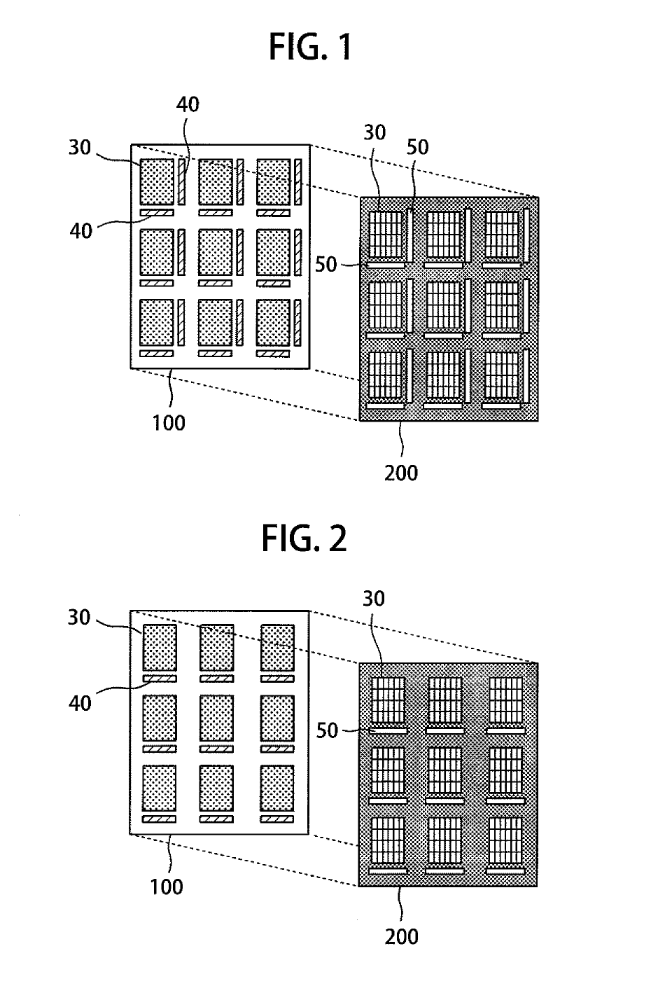

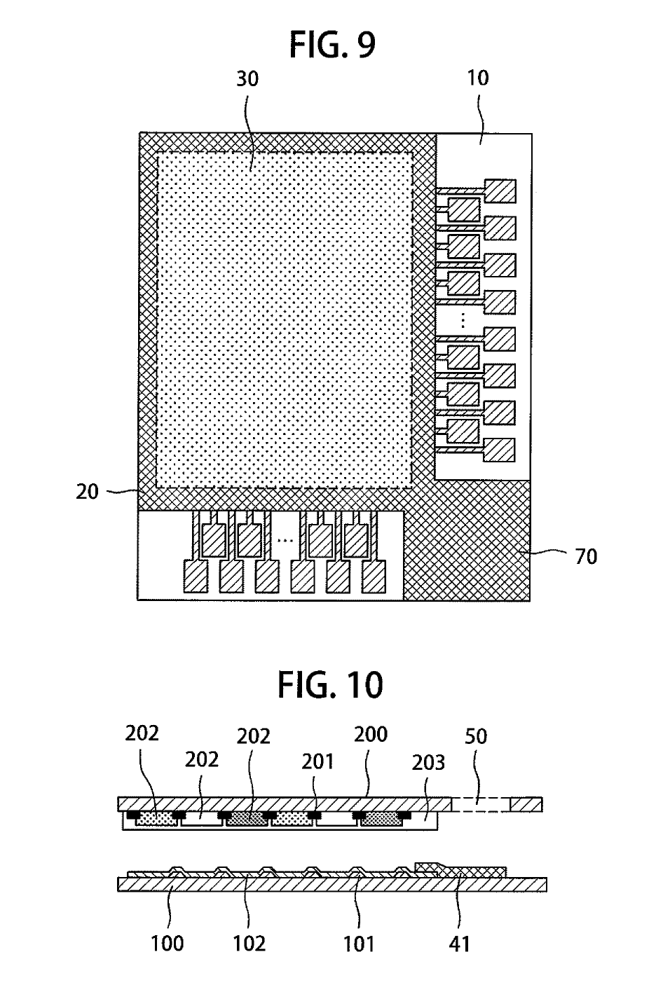

FIG. 1 shows an example of a mother substrate illustrating a first embodiment of the present invention. In FIG. 1, on a mother TFT substrate 100, plural TFT substrates 10 (shown in FIG. 9) are formed each of which is made up of a display region 30 and terminal portions 40. On a mother opposed substrate 200, plural opposed substrates 20 (shown in FIG. 9) are formed. By bonding the mother TFT substrate 100 and the mother opposed substrate 200, display regions 30 formed on the mother opposed substrate 200 are matched with the display regions 30 formed on the mother TFT substrate 100. In the present embodiment, color filters are formed on the display region 30 of the opposed substrate 20.

In FIG. 1, the mother opposed substrate 200 and the mother TFT substrate 100 are bonded with a sealing material and a liquid crystal is added dropwise after the sealing material is formed, in a similar manner to FIG. 17.

In FIG. 1, the mother opposed substrate 200 is made of plastic with a thickness of 200 μm or less. On the mother opposed substrate 200, terminal openings 50 are formed at portions corresponding to the terminal portions 40 formed on the mother TFT substrate 100. By forming the terminal openings 50 thus beforehand on the mother opposed substrate 200, it is possible to eliminate the need for a half cutting process when individual liquid crystal display panels are separated from the mother substrate in the subsequent process. Thus it is possible to remarkably increase a throughput and a yield in a separating process.

By setting the thickness of the mother opposed substrate 200 at 200 μm or less, the terminal openings 50 can be formed by a simple and inexpensive method using a Thomson blade. Further, the terminal openings 50 can be machined in a short time also by laser cutting, water jet cutting, and so on.

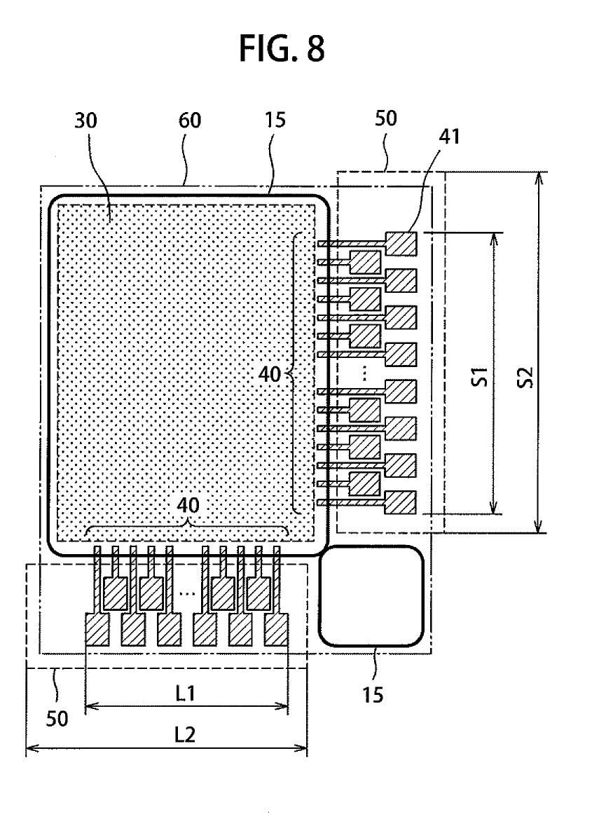

FIG. 8 is a plan view showing a state of the display region 30, the terminal portions 40, and the terminal openings 50 when the mother TFT substrate 100 and the mother opposed substrate 200 are stacked. In FIG. 8, terminals 41 are formed to be staggered in two rows. On a long side of the display region 30, the terminal opening 50 has a width S2 not smaller than a width S1 of the terminal portion 40. On a short side of the display region 30, the terminal opening 50 has a width L2 not smaller than a width L1 of the terminal portion 40.

A cutting line 60 shown in FIG. 8 is formed inside the ends of the terminal openings 50. Thus the terminal portions 40 of the TFT substrate 10 can be exposed with certainty. The cutting line 60 of FIG. 8 determines the outside shape of the liquid crystal display panel. The liquid crystal display panel includes not only the display region 30 and the terminal portions 40 but also a cutting margin 70 on the right corner of FIG. 9.

The first embodiment of the present invention is characterized by forming a sealing material 15 on the cutting margin 70 as well. By forming the sealing material 15 on the cutting margin 70 as well, it is possible to prevent the opposed substrate 20 and the TFT substrate 10 from being erroneously peeled off in the handling of the liquid crystal display panel.

FIG. 9 is a plan view showing a state in which the liquid crystal display panel is cut from the mother substrate along the cutting line 60 of FIG. 8. As shown in FIG. 8, the terminal portions 50 of the mother opposed substrate 200 are formed beforehand. Thus as shown in FIG. 9, the terminal portions 40 on the TFT substrate 10 can be exposed without half cutting. In FIG. 9, the opposed substrate 20 and the TFT substrate 10 are bonded with the sealing material 15 not only around the display region 30 but also on the cutting margin 70.

FIG. 2 shows another form of the configuration of the mother substrate according to the present embodiment. In FIG. 2, the terminal portions 40 are formed only on the short sides of the display regions 30 in the plural TFT substrates 10 formed on the mother TFT substrate 100. This arrangement is used for, for example, small liquid crystal displays of cellular phones and the like.

In FIG. 2, the terminal openings 50 are formed on the mother opposed substrate 200 so as to correspond to the terminal portions 40 formed on the mother TFT substrate 100. Also in FIG. 2, the mother opposed substrate 200 is made of plastic with a thickness of 200 μm or less. The terminal openings 50 are formed on the mother opposed substrate 200 in a similar manner to FIG. 1.

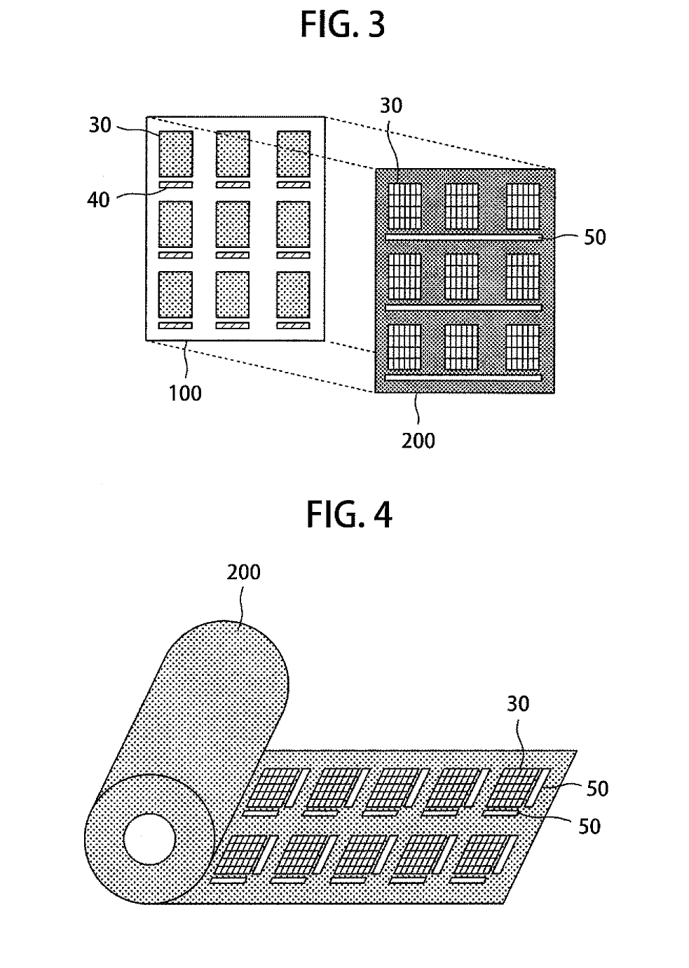

FIG. 3 shows still another form of the configuration of the mother substrate according to the present embodiment. In FIG. 3, the terminal portions 40 are formed only on the short sides of the display regions 30 in the plural TFT substrates 10 formed on the mother TFT substrate 100, as in FIG. 2. In FIG. 3, on the mother opposed substrate 200, the terminal openings 50 are formed which are shared by the plural terminal portions 40 formed on the mother TFT substrate 100.

By forming the terminal openings 50 shared by the plural terminal portions 40, it is possible to shorten a process for forming the terminal openings 50 on the mother opposed substrate 200. Also in FIG. 3, the mother opposed substrate 200 is made of plastic with a thickness of 200 μm or less. The terminal openings 50 shared by the plural terminals 41 are formed on the mother opposed substrate 200 in a similar manner to FIG. 1.

FIG. 4 shows an example of the form of the mother opposed substrate 200. The mother opposed substrate 200 has a small thickness of 200 μm or less and thus can be rolled up, thereby remarkably reducing a work space. The individual opposed substrates 20 formed on the mother opposed substrate 200 of FIG. 4 are shaped as in FIG. 1. In other words, the terminal openings 50 are formed on two of the outer sides of the display region 30 having color filters 202 formed thereon.

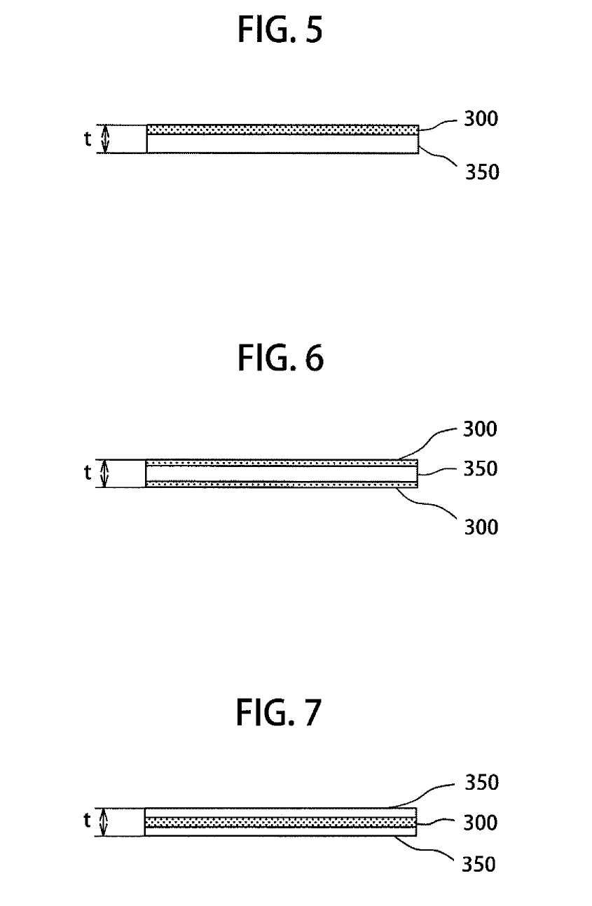

FIG. 5 shows an example of the mother opposed substrate 200 or the mother TFT substrate 100 which can be used for the first embodiment of the present invention. The substrate of FIG. 5 has a laminated structure of a flexible plastic layer 350 and a glass layer 300 having high heat resistance and a low thermal expansion coefficient. The substrate has a thickness of 200 μm or less, including the plastic layer and the glass layer 300. Such a substrate is applicable to, for example, the TFT substrate 10 having TFTs 101 and the like formed on the glass layer 300.

FIG. 6 shows another example of the mother opposed substrate 200 or the mother TFT substrate 100 which can be used for the first embodiment of the present invention. In the substrate of FIG. 6, the flexible plastic layer 350 is sandwiched by the glass layers 300 having high heat resistance and a low thermal expansion coefficient.

In the configuration of FIG. 6, the plastic layer 350 is sandwiched by the glass layers 300 and thus it is possible to increase resistance to cracks on the substrate and prevent a warp of the substrate. The substrate of FIG. 6 also has a thickness of 200 μm or less in total.

FIG. 7 shows another example of the mother opposed substrate 200 or the mother TFT substrate 100 which can be used for the first embodiment of the present invention. In the substrate of FIG. 7, the glass layer 300 having high heat resistance and a low thermal expansion coefficient serves as a core layer and both surfaces of the glass layer 300 are covered with the plastic layers 350 having high flexibility.

In the configuration of FIG. 7, both surfaces of the glass layer 300 are covered with the plastic layers 350. Thus it is possible to increase resistance to cracks on the substrate and prevent a warp of the substrate. The substrate of FIG. 6 also has a thickness of 200 μm or less in total.

FIG. 10 shows a schematic sectional structure of a part of the mother substrate including the liquid crystal display panel according to the present embodiment. In FIG. 10, formed on the mother TFT substrate 100 are the TFTs 101 and wires 102 for connecting the TFTs 101. The terminals 41 are formed in the terminal portions 40 located on the periphery of the TFT substrate 10.

In FIG. 10, on the side of the mother opposed substrate 200, a black matrix 201 and color filters 202 of red, green, blue, and so on are formed. A counter electrode 203 is formed to cover the color filters 202. In FIG. 10, liquid crystal molecules are moved by an electric field between pixel electrodes (not shown) on the mother TFT substrate 100 and the counter electrode 203 formed on the mother TFT substrate 100, so that an amount of light passing through a liquid crystal layer is controlled.

In FIG. 10, the terminal openings 50 are formed on the mother opposed substrate 200. In a state in which the terminal openings 50 are formed, the mother TFT substrate 100 and the mother opposed substrate 200 are bonded to each other. Thus a process for exposing the terminal portions 40 by half cutting is not necessary when the individual liquid crystal display panels are separated from the mother substrate.

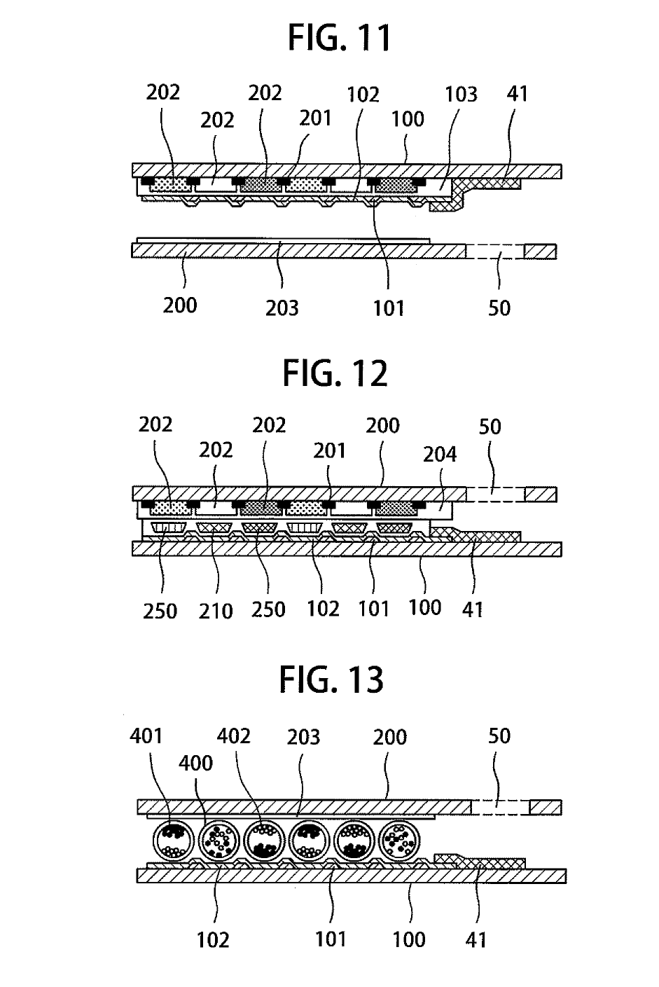

FIG. 11 is a sectional view showing a liquid crystal display having a different structure from FIG. 10. In the liquid crystal display of FIG. 11, the color filters 202 and the black matrix 201 are formed on the side of the TFT substrate 10. In the liquid crystal display of FIG. 10, it is necessary to correctly align the opposed substrate 20 and the TFT substrate 10 in order to correctly match the pixel electrodes formed on the TFT substrate 10 and the color filters 202 formed on the opposed substrate 20.

In contrast to this configuration, in the liquid crystal display of FIG. 11, the color filters 202 are formed on the side of the TFT substrate 10. Thus the TFT substrate 10 and the opposed substrate 20 may be roughly aligned with each other. Therefore, it is possible to increase the throughput of the process and a yield affected by the alignment of the substrates.

In FIG. 11, the black matrix 201 and the color filters 202 of red, green, and blue are formed on the side of the TFT substrate 10 formed on the mother TFT substrate 100, and a flattening film 103 made of resin is formed thereon. On the flattening film 103, the TFTs 101, the wires 102, and so on are formed. On the side of the opposed substrate 20 formed on the mother opposed substrate 200, the counter electrode 203 is formed. Since the counter electrode 203 is formed with a flat surface, the mother opposed substrate 200 and the mother TFT substrate 100 may be roughly aligned with each other.

In FIG. 11, on the side of the mother opposed substrate 200, the terminal openings 50 are formed beforehand so as to correspond to the terminal portions 40 of the mother TFT substrate 100. Although it is necessary to align the terminal portions 40 of the mother TFT substrate 100 and the terminal openings 50 of the mother opposed substrate 200, high accuracy is not necessary as the alignment of the pixel electrodes and the color filters 202. As described above, the first embodiment of the present invention is also applicable with no difficulties to the liquid crystal display having the color filters 202 formed on the side of the TFT substrate 10.

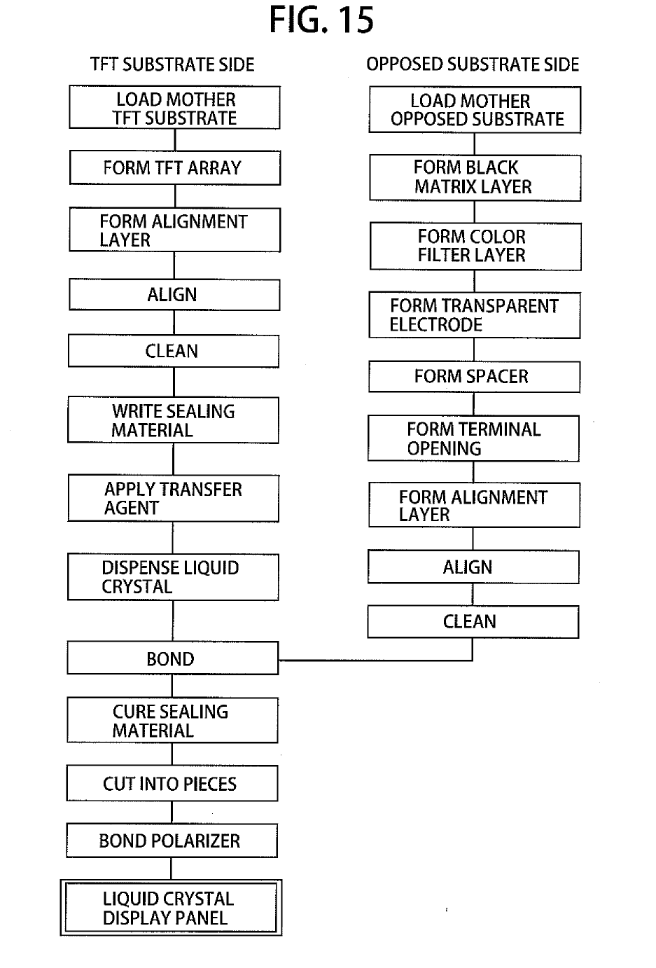

FIG. 15 is a flowchart showing a manufacturing method of the liquid crystal display panel according to the first embodiment of the present invention. FIG. 15 shows the manufacturing method of the liquid crystal display panel shown in FIG. 10. In FIG. 15, in a process on the sides of the TFT substrates 10, the mother TFT substrate 100 made of glass is loaded and a TFT array is formed thereon. After that, an alignment layer is applied thereon, alignment is performed, and the sealing material is formed around the display region 30. Next, a transfer agent for electrically connecting the TFT substrates 10 and the opposed substrates 20 is applied, and then a liquid crystal is added dropwise.

In a process on the side of the mother opposed substrate 200, the substrate made of plastic with a thickness of 200 μm or less is loaded, the black matrix 201 is formed thereon, and the color filters 202 are formed. A transparent electrode serving as the counter electrode 203 is formed on the color filters 202, and then spacers are formed. After that, the terminal openings 50 are formed which characterize the first embodiment of the present invention. In this state, a color filter maker supplies the mother opposed substrate 200 to a LCD panel maker.

The LCD panel maker applies an alignment layer to the purchased mother opposed substrate 200 and then performs alignment thereon. After that, the mother opposed substrate 200 is cleaned and is bonded to the foregoing mother TFT substrate 100. Further, the sealing material is heated or cured by ultraviolet rays, so that the mother substrate is completed.

After that, the mother substrate is cut into the individual liquid crystal display panels. Next, polarizers are bonded to the opposed substrates 20 and the TFT substrates 10, so that the liquid crystal display panels are completed. In the above explanation, the sealing material is formed on the side of the mother TFT substrate 100 and the liquid crystal is added dropwise to the mother TFT substrate 100. Conversely, the sealing material may be formed on the side of the mother opposed substrate 200 and the liquid crystal may be added dropwise to the mother opposed substrate 200.

### Second Embodiment

The first embodiment described an example in which the present invention is applied to a liquid crystal display. The present invention is applicable not only to a liquid crystal display but also to other display devices. FIG. 12 is a sectional view of an organic electroluminescent display. Also in the organic electroluminescent display, plural organic electroluminescent display panels are formed in a mother substrate. In FIG. 12, a mother opposed substrate 200 is formed of a plastic substrate. The plastic substrate has a thickness of 200 μm or less.

In FIG. 12, TFTs 101 and wires 102 are formed on a mother TFT substrate 100 and an organic electroluminescent layer for emitting light of red, green, blue, and so on is formed on the wires 102. The organic electroluminescent layer is formed of plural layers. The organic electroluminescent layer is sandwiched by a cathode electrode and an anode electrode and is fed with a voltage to emit light.

On the side of the mother opposed substrate 200, color filters 202 of red, green, blue, and so on are formed. Since the organic electroluminescent display is self-luminous, the color filters 202 are originally unnecessary for the organic electroluminescent display. However, in the present embodiment shown in FIG. 12, the color filters 202 are used to obtain a sharper spectrum. Between the color filters 202, a black matrix 201 for improving a contrast is formed. The characteristics of the organic electroluminescent layer deteriorate due to moisture and thus a drying material 204 is disposed on the side of an opposed substrate 20 so as to cover the color filters 202.

Also in the organic electroluminescent display of FIG. 12, plural TFT substrates 10 are formed on the mother TFT substrate 100, the plural opposed substrates 20 are formed on the mother opposed substrate 200, and the mother opposed substrate 200 and the mother TFT substrate 100 are bonded to each other to form the mother substrate. After that, the mother substrate is divided to form the individual organic electroluminescent display panels.

In FIG. 12, terminals 41 are formed in the terminal portions 40 of the mother TFT substrate 100, and terminal openings 50 are formed on the mother opposed substrate 200. This configuration is similar to that of the liquid crystal display described in the first embodiment. As described above, also in the case of the organic electroluminescent display, the application of the present invention eliminates the need for half cutting when the individual organic electroluminescent display panels are separated from the mother substrate, thereby improving a process yield and a process throughput.

### Third Embodiment

FIG. 13 shows an example in which the present invention is applied to an electrophoretic panel. In FIG. 13, plural TFT substrates 10 are formed on a mother TFT substrate 100 and plural opposed substrates 20 are formed on a mother opposed substrate 200. On the mother TFT substrate 100, TFTs 101 and wires 102 are formed. On the mother opposed substrate 200, a counter electrode 203 is formed. Between the opposed substrates 20 and the TFT substrates 10, display capsules 400 are sandwiched. The display capsule 400 contains black particles 401 and white particles 402 and an image is formed by changing a ratio of the black particles 401 or the white particles 402 by an electric field on the sides of the opposed substrates 20.

In FIG. 13, terminals 41 are formed in terminal portions 40 of the mother TFT substrate 100 and terminal openings 50 are formed on portions on the side of the mother opposed substrate 200 so as to correspond to the terminal portions 40. The mother opposed substrate 200 of FIG. 13 is formed of a plastic substrate with a thickness of 200 μm or less.

In FIG. 13, the terminal openings 50 are formed beforehand on the mother opposed substrate 200. Thus it is not necessary to perform half cutting on the terminal portions 40 when individual electrophoretic panels are separated from a mother substrate. It is therefore possible to increase a throughput and a yield in a separating process.

### Fourth Embodiment

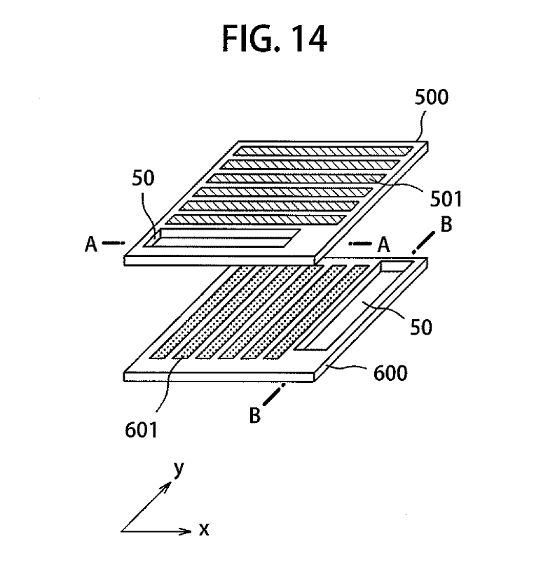

FIG. 14 shows an example in which the present invention is applied to a passive display device. In the following explanation, a liquid crystal display will be discussed as an example. In FIG. 14, plural x electrodes 501 extend in x direction on an x substrate 500. Further, plural y electrodes 601 extend in y direction on a y substrate 600. A liquid crystal is sandwiched between the x substrate 500 and the y substrate 600. Pixels are formed at the points of intersection of the x electrodes 501 and the y electrodes 601.

In FIG. 14, the x substrate 500 and the y substrate 600 are both made of plastic with a thickness of 200 μm or less. In FIG. 14, the ends of the x electrodes 501 and the y electrodes 601 serve as terminal portions 40. Thus on the x substrate 500 and the y substrate 600, terminal openings 50 are formed so as to correspond to the terminal portion 40.

FIG. 14 shows only one liquid crystal display panel out of a mother substrate on which the plural x substrates 500 are formed and a mother substrate on which the plural y substrates 600 are formed. In actual cutting into liquid crystal display panels, the mother substrates are cut along, for example, line A-A or line B-B of FIG. 14.

Also in the present embodiment, the terminal openings 50 are formed beforehand on the mother substrates. Thus it is not necessary to perform half cutting when the individual liquid crystal display panels are separated from the mother substrates, thereby increasing a throughput and a yield in a separating process.

What is claimed is:

1. A mother opposed substrate that is opposed to a mother TFT substrate having a plurality of TFT substrates and has a plurality of opposed substrates disposed in opposition to the TFT substrates, the TFT substrate having terminal portions and a display region in which pixels made up of TFTs and pixel electrodes are formed in a matrix,
wherein the mother opposed substrate has terminal openings formed on portions corresponding to the terminal portions formed on the mother TFT substrate, and
the mother opposed substrate is made of plastic with a thickness of 200 μm or less.

2. The mother opposed substrate according to claim 1, wherein the mother opposed substrate has a side longer than other sides of the mother opposed substrate and can be rolled up.

3. A manufacturing method of a display device formed of a pair of a first substrate having a display region and terminal portions formed thereon and a second substrate, the method comprising the steps of:
forming the plurality of first substrates on a mother first substrate;
forming the second substrates on a mother second substrate so as to correspond to the display regions of the first substrates and forming terminal openings on the mother second substrate so as to correspond to the terminal portions of the first substrates, the mother second substrate being made of plastic with a thickness of 200 μm or less;
forming a mother substrate by bonding the mother first substrate and the mother second substrate; and
separating the pair of the first substrate and the second substrate from the mother substrate.

4. The manufacturing method according to claim 3, wherein a splitting line that splits the pair of the first substrate and the second substrate from the mother substrate has at least one side located inside the terminal opening.

5. A manufacturing method of a liquid crystal display formed of a pair of a TFT substrate and an opposed substrate having color filters and spacers, the TFT substrate having terminal portions and a display region in which pixels including TFTs and pixel electrodes are formed in a matrix,
the method comprising the steps of:
forming the plurality of TFT substrates on a mother TFT substrate;
forming the plurality of opposed substrates on a mother opposed substrate so as to correspond to the display regions of the TFT substrates, the mother opposed substrate being made of plastic with a thickness of 200 μm or less;
forming terminal openings on portions of the mother opposed substrate so as to correspond to the terminal portions of the TFT substrates, after forming the color filters and the spacers;
forming a mother substrate by bonding the mother TFT substrate and the mother opposed substrate; and
separating the pair the TFT substrate and the opposed substrate from the mother substrate.

6. A display device comprising a first substrate having a display region and terminal portions and a second substrate opposed to the first substrate,
wherein the second substrate is made up of a first region including a display region and a second region not including a display region,
the second substrate has terminal openings formed in regions corresponding to the terminal portions of the first substrate,
the second region of the second substrate is not opposed to the display region of the first substrate and the terminal portions of the first substrate,
the first substrate and the first region of the second substrate are bonded with a sealing material, and
the first substrate and the second region of the second substrate are bonded with the sealing material.

7. A manufacturing method of a passive display device,
the passive display device comprising:
a first substrate having a plurality of first electrodes formed to extend in a first direction, and
a second substrate having a plurality of second electrodes formed to extend in a second direction,
the first and second electrodes having pixels formed on points of intersection of the first and second electrodes so as to constitute a display region, the plurality of first electrodes having a first terminal portion formed on ends of the first electrodes, the plurality of second electrodes having a second terminal portion formed on ends of the second electrodes,
the method comprising the steps of:
forming the plurality of first substrates on a mother first substrate made of plastic with a thickness of 200 μm or less;
forming the plurality of second substrates on a mother second substrate made of plastic with a thickness of 200 μm or less;
forming terminal openings on portions of the mother first substrate so as to correspond to second terminals formed on the second substrates;
forming terminal openings on portions of the mother second substrate so as to correspond to first terminals formed on the first substrates;
forming a mother substrate by bonding the mother first substrate and the mother second substrate; and
separating the individual passive display devices from the mother substrate.
